(19) United States
(12) Patent Application Publication
(10) Pub. No.: US 2023/0163163 A1
(43) Pub. Date: May 25, 2023

(54) SEMICONDUCTOR DEVICE WITH INTEGRATED METAL-INSULATOR-METAL CAPACITORS

(71) Applicant: Taiwan Semiconductor Manufacturing Co., Ltd., Hsinchu (TW)

(72) Inventors: Wei-Zhong Chen, Taipei City (TW); JeiMing Chen, Tainan City (TW); Tze-Liang Lee, Hsinchu (TW)

(21) Appl. No.: 17/717,731

(22) Filed: Apr. 11, 2022

Related U.S. Application Data
(60) Provisional application No. 63/264,386, filed on Nov. 22, 2021.

(51) Int. Cl. H01L 49/02

(52) U.S. Cl. CPC H01L 28/87

(57) ABSTRACT

A method of forming a semiconductor device includes: forming an interconnect structure over a substrate; forming an etch stop layer over the interconnect structure; and forming a first multi-layered structure over the etch stop layer, which includes: forming a first conductive layer over the etch stop layer; treating an upper layer of the first conductive layer with a plasma process; and forming a second conductive layer over the treated first conductive layer. The method further includes: patterning the first multi-layered structure to form a first electrode; forming a first dielectric layer over the first electrode; forming a second multi-layered structure over the first dielectric layer, the second multi-layered structure having the same layered structure as the first multi-layered structure; and patterning the second multi-layered structure to form a second electrode.

### PRIORITY CLAIM AND CROSS-REFERENCE

This application claims the benefit of U.S. Provisional Application No. 63/264,386, filed on Nov. 22, 2021 and entitled “Pattern_TiN Electrode Surface Roughness Improvement by Nitrogen Treatment,” which application is hereby incorporated herein by reference in its entirety.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-14 illustrate cross-sectional views of a semiconductor device at various stages of manufacturing, in an embodiment.

FIG. 15 illustrates a schematic view of capacitors coupled in parallel, in an embodiment.

FIG. 16 illustrates a cross-sectional view of a semiconductor device, in another embodiment.

FIG. 17 is a flow chart of a method of forming a semiconductor device, in some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Throughout the discussion herein, unless otherwise specified, the same or similar reference numerals in different figures refer to the same or similar element formed by a same or similar process using a same or similar material(s).

In accordance with some embodiments, metal-insulator-metal (MIM) capacitors are formed in the back end of line processing (BEOL) of a semiconductor die. The MIM capacitors are formed by successively forming a bottom electrode, a first high-k dielectric layer, a middle electrode, a second high-k dielectric layer, and a top electrode over an interconnect structure of the semiconductor die. At least the bottom electrode and the middle electrode are formed as having a tri-layered structure, where the tri-layered structure includes an amorphous material sandwiched between two layers of a polycrystalline material. In some embodiments, the tri-layered structure is formed by forming a first layer of the polycrystalline material, converting an upper layer of the first layer of the polycrystalline material into the amorphous material using a plasma process, and forming a second layer of the polycrystalline material over the amorphous material. In some embodiments, the amorphous material breaks the columnar crystalline structure of the polycrystalline material and reduces the surface roughness of at least the bottom electrode and the middle electrode. The reduced surface roughness alleviates or avoids performance degradation due to high surface roughness.

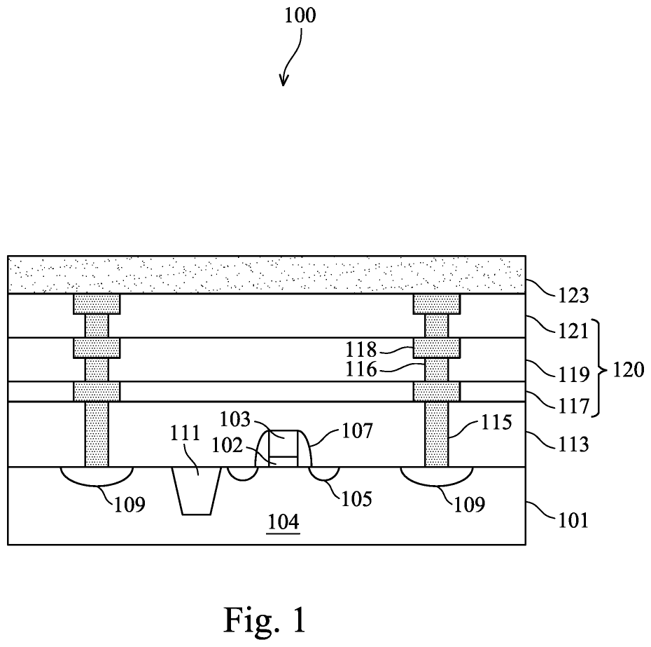

FIGS. 1-14 illustrate cross-sectional views of a semiconductor device 100 at various stages of manufacturing, in an embodiment. The semiconductor device 100 is an integrated circuit (IC) device (also referred to as an IC die) with integrated metal-insulator-metal (MIM) capacitors formed during back end of line (BEOL) processing. As illustrated in FIG. 1, the semiconductor device 100 includes a substrate 101, transistors 106 formed in or on the substrate 101, an interlayer dielectric (ILD) 113, an interconnect structure 120, and an etch stop layer 123.

The substrate 101 may be a semiconductor substrate, such as a bulk semiconductor, a semiconductor-on-insulator (SOI) substrate, or the like, which may be doped (e.g., with a p-type or an n-type dopant) or undoped. The substrate 101 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 101 includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

Transistors 106 are formed in/on the substrate 101 in an active region 104 of the substrate 101. The active region 104 may be, e.g., a fin that protrudes above the substrate 101. The fin may be formed of a semiconductor material (e.g., Si, or SiGe), and may be formed by, e.g., etching trenches in the substrate 101. The transistors 106 may be formed using any suitable method(s) known and used in the art. Each of the transistors 106 may be, e.g., a fin field-effect transistor (FinFET), and may include source/drain regions 105, a gate dielectric 102, a gate electrode 103, and gate spacers 107. Insulation regions 111, such as shallow trench isolation (STI) regions, are formed in the substrate 101 adjacent to the transistors 106. Note that FinFET is used as a non-limiting example. The transistors 106 may be other types of transistors, such as planar transistors. Besides transistors 106, other electrical components, such as resistors, inductors, diodes, or the like, may also be formed in/on the substrate 101. FIG. 1 further illustrates conductive regions 109, which are used to illustrate any conductive features formed in/on the substrate 101. For example, each of the conductive regions 109 may be a terminal (e.g., the source/drain region 105, or the gate electrode 103) of a transistor 106, a terminal of a resistor, a terminal of an inductor, a terminal of a diode, or the like. Note that throughout the description herein, unless otherwise specified, the term “conductive feature,” “conductive region,” or “conductive material” refer to electrically conductive feature, electrically conductive region, or electrically conductive material, and the terms “couple” or “coupled” refers to electrical coupling.

Still referring to FIG. 1, after the electrical components (e.g., transistors 106) are formed in/on the substrate 101, the ILD 113 is formed over the substrate 101 around the gate structures (e.g., 102/103) of the transistors 106. The ILD 113 may be formed of a dielectric material, and may be deposited by any suitable method, such as chemical vapor deposition (CVD), plasma-enhanced CVD (PECVD), or flowable CVD (FCVD). Suitable dielectric materials for the ILD 113 include silicon oxide, Phospho-Silicate Glass (PSG), Boro-Silicate Glass (BSG), Boron-Doped Phospho-Silicate Glass (BPSG), undoped Silicate Glass (USG), or the like. Other insulation materials formed by any acceptable process may also be used.

Next, contact plugs 115 are formed in the ILD 113 to be coupled with the conductive regions 109. Contact plugs 115 may be formed by etching openings in the ILD 113 using photolithography and etching techniques, then filling the openings with one or more conductive materials. For example, after the openings in the ILD 113 are formed, a barrier layer comprising an electrically conductive material, such as titanium nitride, tantalum nitride, titanium, tantalum, or the like, may be conformally formed to line the sidewalls and bottoms of the openings. The barrier layer may be formed using a CVD process, such as plasma-enhanced CVD (PECVD). However, other alternative processes, such as sputtering or metal organic chemical vapor deposition (MOCVD), atomic layer deposition (ALD), may alternatively be used. After the barrier layer is formed, a conductive material, such as copper, tungsten, gold, cobalt, combinations thereof, or the like, may be formed to fill the openings to form the contact plugs 115. A planarization process, such as chemical mechanical planarization (CMP), may be performed to remove excess portions of the barrier layer and the conductive material from the upper surface of the ILD 113.

Next, the interconnect structure 120 is formed to interconnect the electrical components formed in/on the substrate 101 to form functional circuits. The interconnect structure 120 includes a plurality of dielectric layers (e.g., 117, 119, 121) and conductive features (e.g., vias 116 and conductive lines 118) formed in the dielectric layers. The dielectric layers 117, 119, and 121 may be made of one or more suitable dielectric materials such as silicon oxide, silicon nitride, low-k dielectric material such as carbon doped oxide, extremely low-k dielectrics such as porous carbon doped silicon dioxide, combinations thereof, or the like. The dielectric layers 117, 119, and 121 may be formed through a suitable process such as CVD, although any suitable process may be utilized. The conductive features (e.g., vias 116 and conductive lines 118) of the interconnect structure 120 may be formed using a suitable method, such as damascene, dual-damascene, or the like. The number of dielectric layers in the interconnect structure 120 and the electrical connection illustrated in FIG. 1 are merely non-limiting examples, as skilled artisans readily appreciate. Other numbers of dielectric layers and other electrical connection are possible and are fully intended to be included within the scope of the present disclosure.

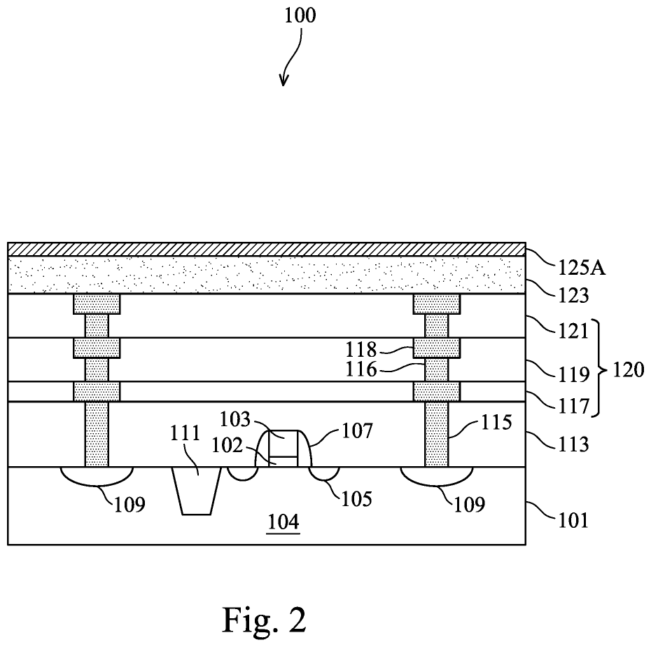

Next, in FIG. 1, the etch stop layer (ESL) 123 is formed over the interconnect structure 120. The ESL 123 is formed of a material having a different etch rate than a subsequently formed conductive layer 125A (see FIG. 2). In an embodiment, the ESL 123 is formed of silicon oxide using PECVD, although other dielectric materials such as nitride, silicon oxynitride, combinations thereof, or the like, and alternative techniques of forming the ESL 123, such as low-pressure CVD (LPCVD), physical vapor deposition (PVD), or the like, could be used.

Referring next to FIG. 2, a conductive layer 125A is formed over the ESL 123. The conductive layer 125A is formed of a conductive material, such as titanium nitride (TiN), tantalum nitride (TaN), tungsten (W), tungsten silicide (WSi), platinum (Pt), aluminum (Al), copper (Cu), or the like, and may be formed by a suitable method such as PVD, CVD, ALD, or the like. In some embodiments, thin films such as the conductive layer 125A formed by, e.g., PVD process in the back end of line (BEOL) process domain (e.g., at temperature less than 400° C.) have a polycrystalline structure, such as a columnar polycrystalline structure. In an example embodiment, the conductive layer 125A is formed of TiN using PVD. A thickness of the conductive layer 125A is between about 100 angstroms and about 1000 angstroms, in some embodiments. A thickness of the conductive layer 125A smaller than 100 angstroms may be too thin to form the bottom electrode for the subsequently formed MIM capacitor, and a thickness of the conductive layer 125A larger than 1000 angstroms may be too thick to pattern in the subsequent patterning process. A deposition power of the PVD process, which is the power of the RF source used to turn the sputtering gas used in the PVD process into plasma, is between about 1 KW and about 30 KW, in some embodiments. A deposition power smaller than 1 KW may not be enough to ignite the sputter gas into plasma and/or may result in too slow of a deposition rate, and a deposition power larger than 30 KW may cause the deposition rate of the conductive layer 125A to be too high to be able to control precisely.

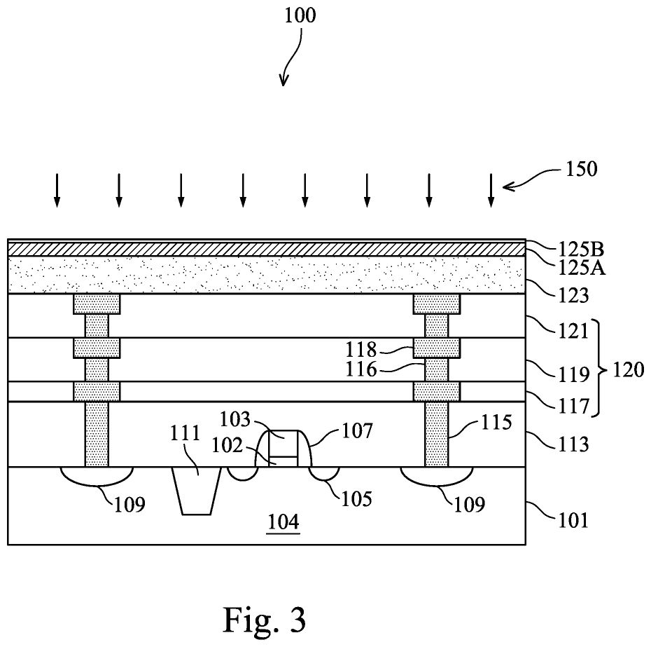

Next, in FIG. 3, a plasma process 150 is performed to convert the upper layer of the conductive layer 125A (e.g., a polycrystalline material) into a layer of an amorphous material, which is illustrated in FIG. 3 as a conductive layer 125B. In some embodiments, the plasma process is performed using a gas source comprising nitrogen gas (N₂), although other suitable gases, e.g., noble gases such as helium (He), argon (Ar), krypton (Kr), or the like, may also be used. In some embodiments, during the plasma process, the gas source is ignited into a plasma, and the ions of the plasma bombard the upper layer of the conductive layer 125A (e.g., a crystalline material), destroying the crystalline structure of the upper layer of the first conductive layer 125A and turning it into an amorphous material.

The plasma process may be preformed with a duration between about 5 seconds and about 30 seconds. An RF power (e.g., power of the RF source used in the plasma process) of the plasma process may be between about 30 W and about 300 W. A thickness of the conductive layer 125B is between about 5 angstroms and about 10 angstroms, in some embodiments. The parameters of the plasma process are controlled to achieve performance targets. For example, if the duration of the plasma process is too short (e.g., <5 seconds), the crystalline structure of the upper layer of the conductive layer 125A may not be sufficiently broken to reduce its surface roughness (more details discussed below). If the duration of the plasma process is too long (e.g., >30 seconds), the conductive layer 125B, which is an electrically conductive amorphous material, may be too thick. Since the electrical resistance of the conductive layer 125B (e.g., an amorphous material) may be higher than that of the conductive layer 125A (e.g., a crystalline material), a thick conductive layer 125B may increase the electrical resistance of the gate electrode formed subsequently above a target resistance value. In addition, a long duration of the plasma process 150 may induce high stress in the conductive layer 125B, which high stress may increase the risk of delamination (e.g., peeling) at the interface between the conductive layer 125B and the subsequently formed conductive layer 125C. If the RF power is too low (e.g., <30 W), the gas source may not be ignited into plasma and/or the plasma process may be too slow. If the RF power is too high (e.g., >300 W), the ion bombardment during the plasma process may be too strong and may etch away the conductive layer 125A and/or the conductive layer 125B. Similarly, if the conductive layer 125B is too thin (e.g., <5 angstroms), it may not break the crystalline structure of the conductive layer 125A sufficiently to reduce its surface roughness, and if the conductive layer 125B is too thick (e.g., >10 angstroms), the electrical resistance of the bottom electrode formed may be too high.

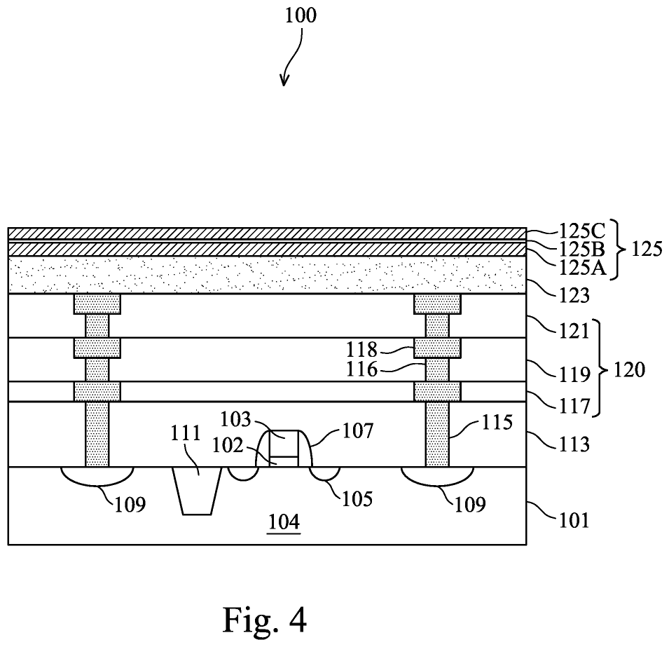

Next, in FIG. 4, a conductive layer 125C is formed over the conductive layer 125B. In the illustrated embodiment, the conductive layer 125C is formed of the same conductive material as the conductive layer 125A using a same formation method, thus details are not repeated. A thickness of the conductive layer 125C is between about 100 angstroms and about 1000 angstroms, in some embodiments. In some embodiments, a PVD process is performed to form the conductive layer 125C, and a deposition power of the PVD process is between about 1 KW and about 30 KW.

The conductive layers 125A, 125B, and 125C form a tri-layered structure 125 (also referred to as a multi-layered structure 125). In an example embodiment, the conductive layers 125A and 125B are formed of polycrystalline TiN, the conductive layer 125B is formed of amorphous TiN. The tri-layered structure 125, with the conductive layer 125B being sandwiched between the conductive layers 125A and 125C, advantageously reduces the surface roughness of the conductive layers 125A and 125C. For example, the surface roughness (e.g., of the upper surface) of the conductive layer 125C is reduced, compared with a reference design where the tri-layered structure 125 is replaced with a thick, single conductive layer formed of the conductive material of the conductive layer 125A (or 125C). In some embodiments, thin films such as the conductive layer 125A formed by PVD process in the back end of line (BEOL) process domain (e.g., at temperature less than 400° C.) have a columnar polycrystalline structure. Thin films with columnar polycrystalline structure, if grown to large thicknesses (e.g., above a few hundred angstroms), may have high surface roughness due to the large differences in the heights of the grains in the columnar polycrystalline structure. For example, the RMS surface roughness for the reference design (e.g., a single conductive layer with a thickness of about 600 angstroms) may be between about 1.8 nm and 2.0 nm. The plasma process 150, which forms the conductive layer 125B in the tri-layered structure 125, breaks the columnar polycrystalline structure of the material (e.g., TiN) of the conductive layers 125A (and 125C), which results in smaller grains and smaller height differences. As a result, the surface roughness of the conductive layer 125C and 125A is reduced. For example, the RMS roughness for the conductive layer 125C may be between about 1.6 nm and about 1.8 nm. In some embodiments, the conductive layer 125B is referred to as an insertion layer, and the tri-layered structure 125 is described as a columnar polycrystalline material (e.g., the material of the conductive layer 125A or 125C) with an embedded insertion layer 125B.

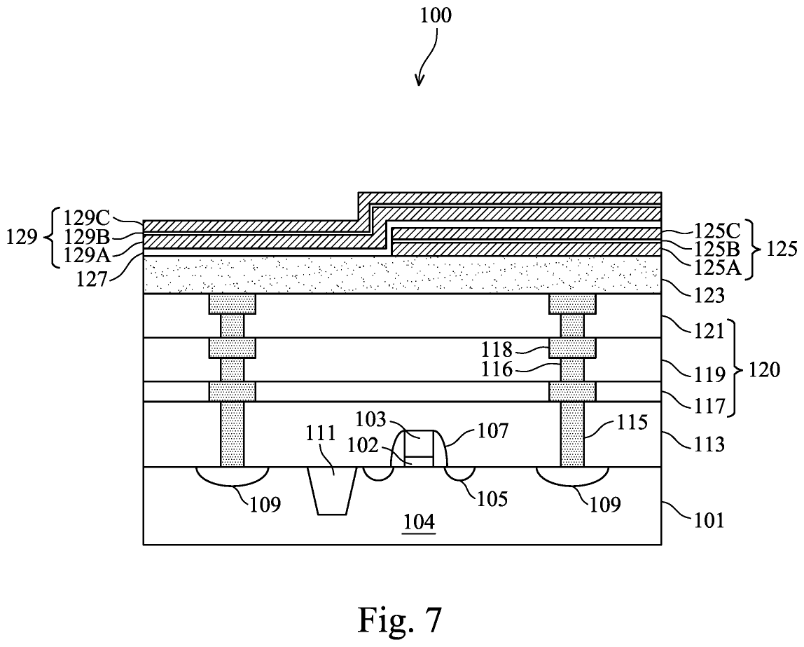

The tri-layered structure 125 is patterned in subsequent processing to form the bottom electrode of an MIM capacitor. In the MIM capacitor, electrode surfaces with high surface roughness may cause corona effect (e.g., high local electrical field), which may negatively affect the performance of the MIM capacitor in terms of breakdown voltage (VBD) and time-dependent dielectric breakdown (TDDB) for the dielectric layer (see, e.g., 127 in FIG. 7) in the MIM capacitor. In addition, high surface roughness may result in a weak interface between the electrode and the subsequently formed dielectric layer (e.g., 127), resulting in, e.g., delamination of the dielectric layer 127. The disclosed tri-layered structure 125, by breaking the columnar polycrystalline structure of the conductive layers 125A and 125C, reduces the surface roughness, thereby alleviating or avoiding the performance issues discussed above.

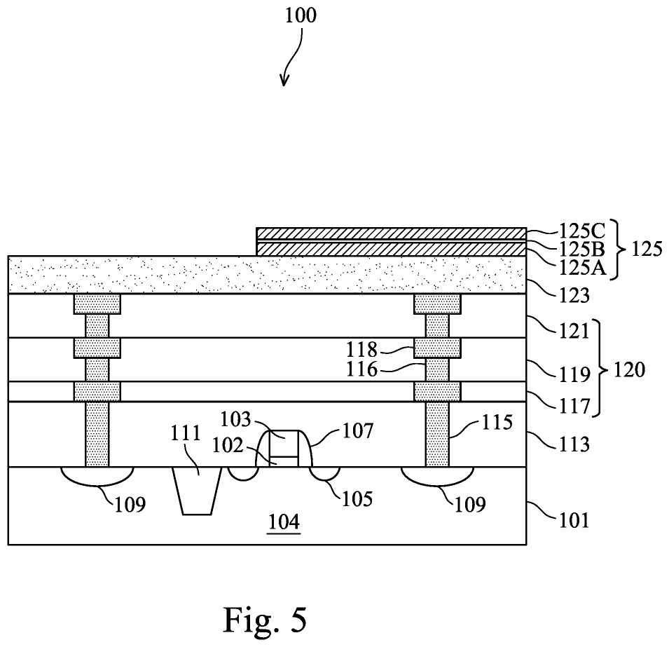

Next, in FIG. 5, the tri-layered structure 125 is patterned to form a bottom electrode 125. In some embodiments, a photoresist layer is formed on the tri-layered structure 125. The photoresist layer is patterned using, e.g., photolithography. An anisotropic etching process is then performed using the patterned photoresist layer as the etching mask. The anisotropic etching process may use an etchant that is selective to (e.g., having a higher etching rate for) the material of the photoresist layer. After the anisotropic etching process, the remaining portion of the tri-layered structure 125 forms the bottom electrode 125. As illustrated in FIG. 5, the bottom electrode 125 covers a first portion (e.g., right portion in FIG. 5) of the ESL 123 and exposes a second portion (e.g., left portion in FIG. 5) of the ESL 123. After the bottom electrode 125 is formed, the patterned photoresist layer is removed by a suitable process, such as ashing.

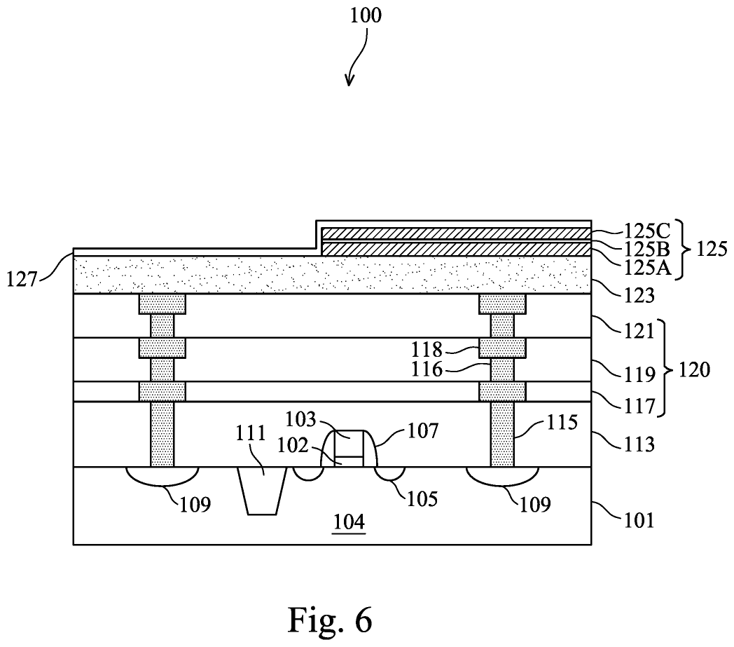

Next, in FIG. 6, a dielectric layer 127 is formed (e.g., conformally) over the bottom electrode 125. The dielectric layer 127 is formed of a high-k dielectric material, in an example embodiment. Example materials for the dielectric layer 127 include HfO₂, ZrO₂, Al₂O₃, Ta₂O₅, TiO₂, La₂O₃, Y₂O₃, HfSiO₄, LaAlO₃, SrTiO₃, Si₃N₄, combinations thereof, or the like. A suitable formation method, such as CVD, PECVD, ALD, or the like, may be used to form the dielectric layer 127. Note that the dielectric layer 127 has a stair shaped cross-section. A first portion (e.g., left portion in FIG. 6) of the dielectric layer 127 contacts and extends along the upper surface of the ESL 123, and a second portion (e.g., right portion in FIG. 6) of the dielectric layer 127 contacts and extends along the upper surface of the bottom electrode 125.

Next, in FIG. 7, conductive layers 129A, 129B, and 129C are formed successively over the dielectric layer 127 to form a tri-layered structure 129. In the illustrated embodiment, the tri-layered structure 129 is the same as the tri-layered structure 125 of FIG. 4. In other words, the conductive layers 129A, 129B, and 129C are the same as the conductive layers 125A, 125B, and 125C, respectively. The materials and the formation method of the tri-layered structure 129 is the same as or similar to that of the tri-layered structure 125, thus details are not repeated.

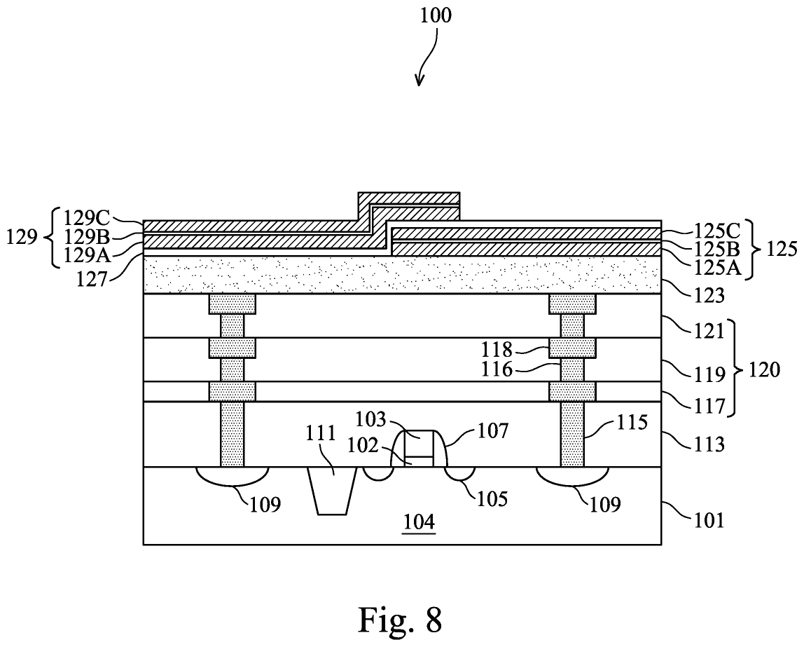

Next, in FIG. 8, the tri-layered structure 129 is patterned to form a middle electrode 129, using, e.g., photolithography and etching techniques. Details are the same as or similar to those discussed above for the bottom electrode 125, thus not repeated here. Note that the middle electrode 129 has a stair-shaped cross-section. A first portion (e.g., lower portion) of the middle electrode 129 is laterally adjacent to the bottom electrode 125, and a second portion (e.g., higher portion) is vertically above (e.g., over) the bottom electrode 125. In FIG. 8, the first portion of the dielectric layer 127 (which contacts and extends along the upper surface of the ESL 123) is covered (e.g., completely covered) by the middle electrode 129, and the second portion of the dielectric layer 127 (which contacts and extends along the upper surface of the bottom electrode 125) is partially exposed by the middle electrode 129.

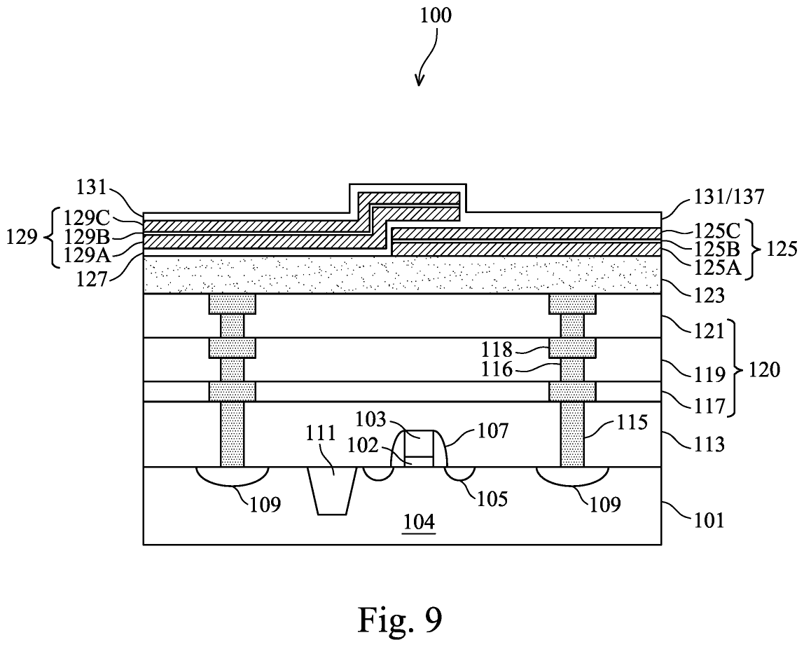

Next, in FIG. 9, a dielectric layer 131 (e.g., a high-k dielectric material) is formed (e.g., conformally) over the middle electrode 129 and over the exposed portion of the dielectric layer 127. In an example embodiment, the dielectric layer 131 is formed of the same material as the dielectric layer 127 using the same or similar formation method, thus details are not repeated. Note that a portion of the dielectric layer 131 contacts and extends along the upper surface and a sidewall of the middle electrode 129, and another portion of the dielectric layer 131 contacts and extends along the exposed portion of the dielectric layer 127. As a result, the exposed portion of the dielectric layer 127 merge with the overlying dielectric layer 131 to form a region of dielectric material (labeled as 131/127 in FIG. 9) that is about twice as thick as the dielectric layer 131 (or 127), in some embodiments.

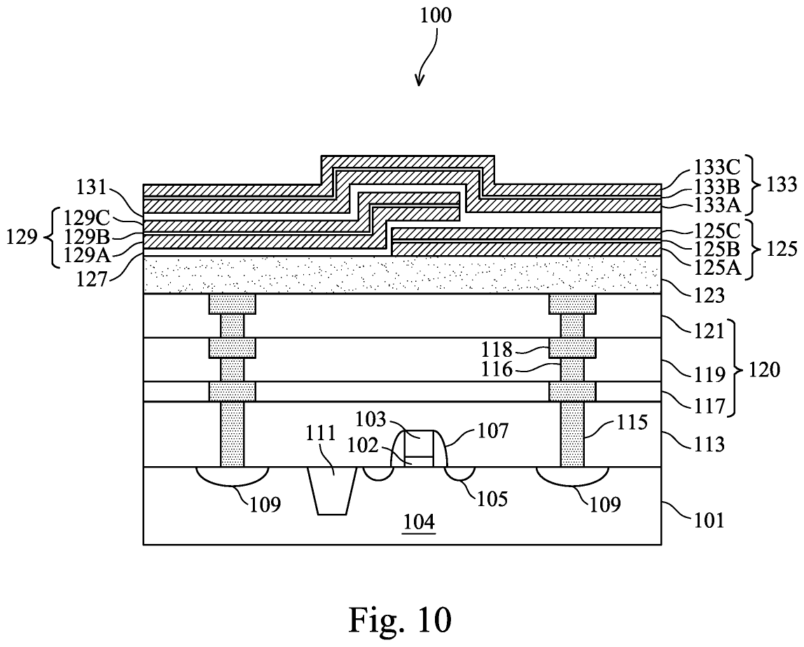

Next, in FIG. 10, conductive layers 133A, 133B, and 133C are formed successively over the dielectric layer 131 to form a tri-layered structure 133. In the illustrated embodiment, the tri-layered structure 133 is the same as the tri-layered structure 125 of FIG. 4. In other words, the conductive layers 133A, 133B, and 133C are the same as the conductive layers 125A, 125B, and 125C, respectively. The materials and the formation method of the tri-layered structure 133 is the same as or similar to that of the tri-layered structure 125, thus details are not repeated.

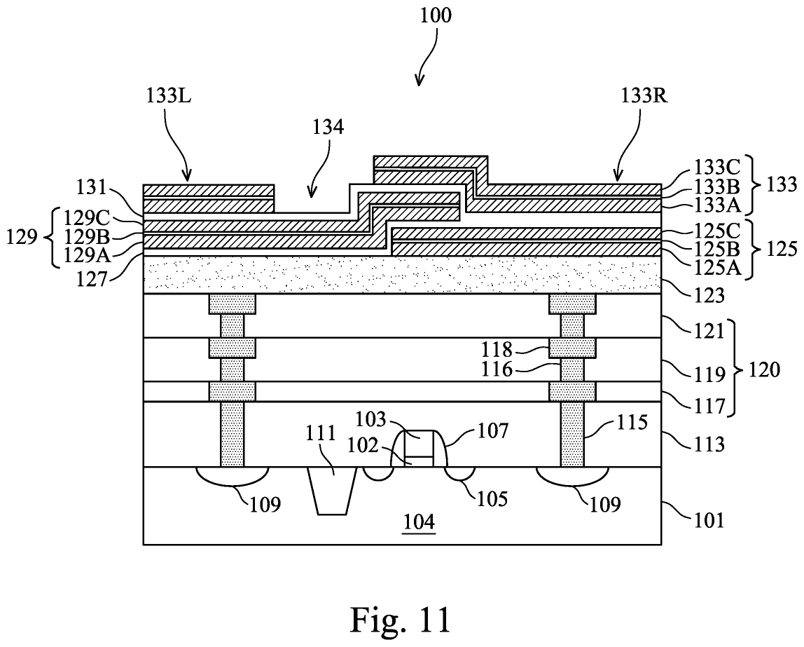

Next, in FIG. 11, the tri-layered structure 133 is patterned using, e.g., photolithography and etching techniques. In the illustrated embodiment, an opening 134 is formed in the tri-layered structure 133 to expose the dielectric layer 131, and the tri-layered structure 133 is separated into two separate portions, e.g. a left portion 133L and a right portion 133R. The right portion 133R has a stair-shaped cross-section and forms the top electrode 133R. In the example of FIG. 11, a first portion of the top electrode 133R is laterally adjacent to the middle electrode 129, and a second portion of the top electrode 133R is vertically above (e.g., over) the middle electrode 129. In the illustrated embodiment, a portion of the middle electrode 129 is vertically interposed between the bottom electrode 125 and a portion of the top electrode 133R. In other words, a portion of the top electrode 133R, a portion of the middle electrode 129, and a portion of the bottom electrode 125 are vertically stacked along a same vertical line. Note that the dielectric layers 127 and 131 separate the bottom electrode 125, the middle electrode 129, and the top electrode 133R from each other. In some embodiments, the left portion 133L of the tri-layered structure 133 is removed during the patterning process for the tri-layered structure 133, and only the right portion 133R remains to form the top electrode 133R. As will be discussed in more details below, the bottom electrode 125, the middle electrode 129, and the dielectric layer 127 in-between form a first MIM capacitor. The top electrode 133R, the middle electrode 129, and the dielectric layer 131 in-between form a second MIM capacitor coupled in parallel to the first MIM capacitor.

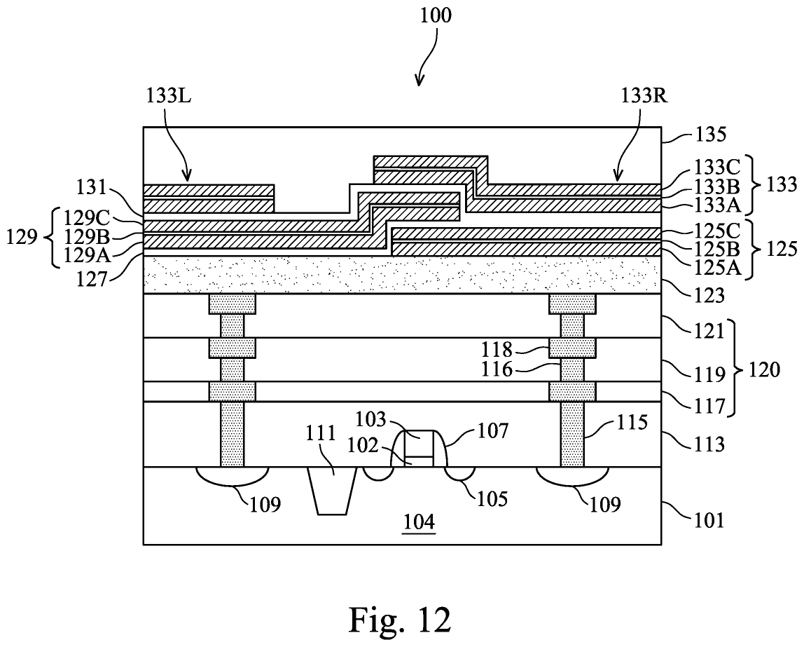

Next, in FIG. 12, a passivation layer 135 is formed over the top electrode 133R. The passivation layer 135 is formed of a suitable dielectric material, such as silicon oxide, a polymer (e.g., polyimide), or the like, using a suitable formation method such as CVD, PECVD, or the like. The passivation layer 135 fills the opening 134 (see FIG. 11). After the passivation layer 135 is formed, a planarization process, such as CMP, may be performed to achieve a level upper surface for the passivation layer 135.

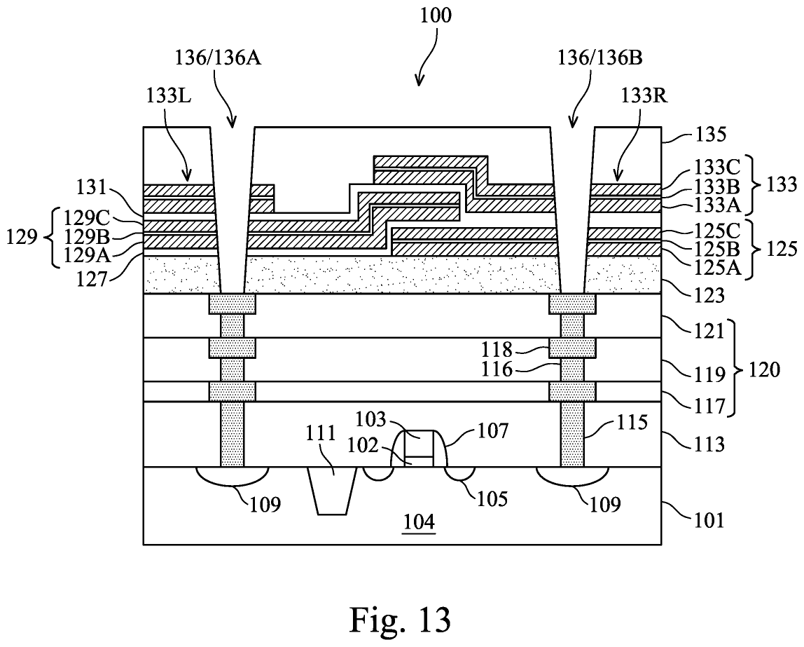

Next, in FIG. 13, openings 136 (e.g., 136A and 136B) are formed to expose the conductive features of the interconnect structure 120. The openings 136 are formed using photolithography and etching techniques, in an embodiment. In the example of FIG. 13, the opening 136A is formed to extends through the passivation layer 135, the left portion 133L of the tri-layered structure 133, the dielectric layer 131, the middle electrode 129, the dielectric layer 127, and the ESL 123. The opening 136B is formed to extends through the passivation layer 135, the top electrode 133R, the dielectric layer 131, the dielectric layer 127, the bottom electrode 125, and the ESL 123.

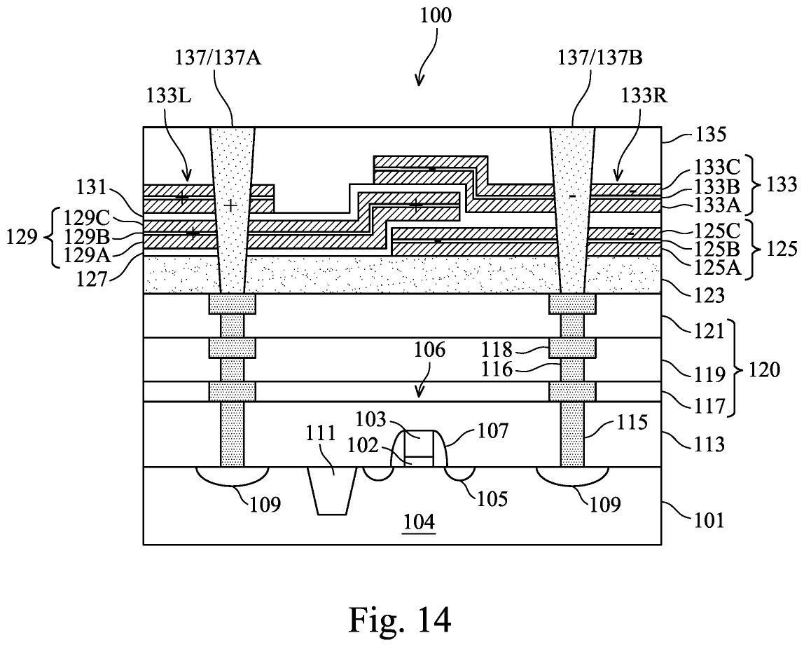

Next, in FIG. 14, one or more conductive materials are formed in the openings 136 to form vias 137 (e.g., 137A and 137B). The vias 137 may be formed by forming a barrier layer to line the sidewalls and bottoms of the openings 136, then fill the openings with a conductive material. Details are the same as or similar to those described above for the formation of the contact plugs 115, thus not repeated here. Note that in FIG. 14, sidewalls of the via 137A contact, thus are electrically coupled to, the left portion 133L of the tri-layer structure 133 and the middle electrode 129. Similarly, sidewalls of the via 137B contact, thus are electrically coupled to, the top electrode 133R and the bottom electrode 125.

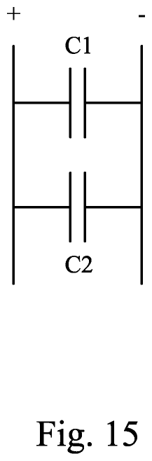

FIG. 14 further illustrates an example electrical connection for the MIM capacitors of the semiconductor device 100. For example, the via 137A is connected to a first voltage supply node (e.g., a positive terminal of a voltage supply), and the via 137B is connected to a second voltage supply node (e.g., a negative terminal of a voltage supply). To facilitate discussion, “+” symbol or “−” symbol is shown on the top electrode 133R, the middle electrode 129, and the bottom electrode 125 to illustrate their electrical connections to the voltage supply. Skilled artisan will readily appreciate that other electrical connections are possible. For example, the “+” symbols and the “−” symbols in FIG. 14 may be switched. Therefore, in the example of FIG. 14, the two MIM capacitors are coupled in parallel between the positive terminal labeled by “+” and the negative terminal labeled by “−”, as illustrated in FIG. 15.

FIG. 15 illustrates a schematic view of the MIM capacitors in FIG. 14, in an embodiment. As illustrated in FIG. 15, a first capacitor C1 and a second capacitor C2 are coupled in parallel between the positive terminal and the negative terminal. The first capacitor C1 may correspond to the MIM capacitor formed by the bottom electrode 125, the middle electrode 129, and the dielectric layer 127 in-between. The second capacitor C2 may correspond to the MIM capacitor formed by the top electrode 133R, the middle electrode 129, and the dielectric layer 131 in-between. The parallel connection of the first capacitors C1 and the second capacitor C2 results in an equivalent capacitor with a larger capacitance, which larger capacitance is the sum of the capacitances of the first capacitor C1 and the second capacitor C2.

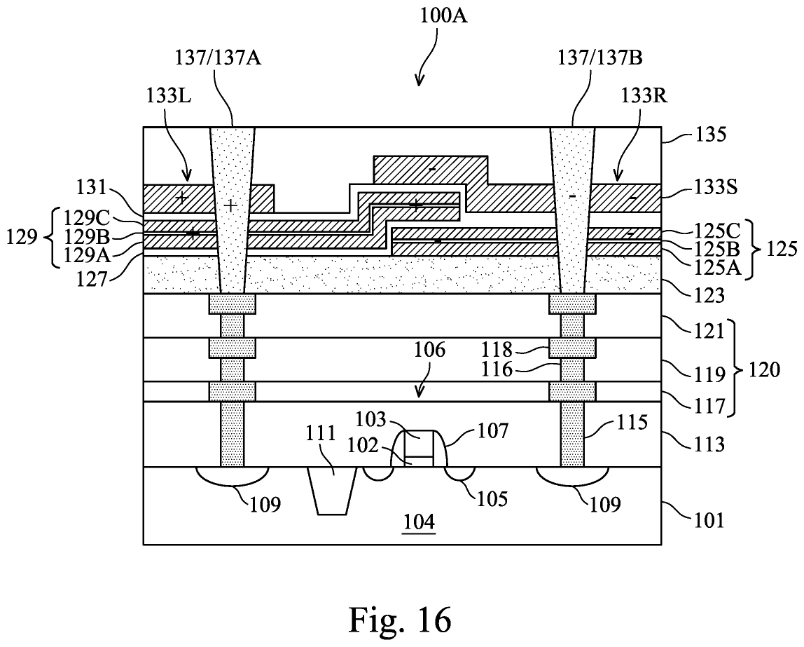

FIG. 16 illustrates a cross-sectional view of a semiconductor device 100A, in another embodiment. The semiconductor device 100A is similar to the semiconductor device 100 of FIG. 14, but the tri-layered structure 133 in FIG. 14 is replaced by a single conductive layer 133S in FIG. 16. In some embodiments, the single conductive layer 133S in FIG. 16 is formed of the same material as the conductive layer 133A (or 133C) in FIG. 14, and has a same thickness as the tri-layered structure 133 in FIG. 14. In other words, to form the single conductive layer 133S in FIG. 16, the conductive layer 133B in the tri-layered structure 133 of FIG. 14 is no longer formed (e.g., the plasma process 150 is not performed), and the material (e.g., TiN) of the conductive layer 133A is grown (e.g., deposited) to the full thickness of the tri-layered structure 133 in FIG. 14. This simplifies the manufacturing process and reduces cost. Note that unlike the tri-layered structures 125 and 129, which has a high-k dielectric material (e.g., 127 or 131) formed thereon, no high-k dielectric material is formed over the single conductive layer 133S to form an MIM capacitor. Therefore, although the single conductive layer 133S has a higher surface roughness than the tri-layered structures 125 and 129, there is no performance loss (e.g., VBD and/or TDDB) caused by the higher surface roughness of the single conductive layer 133S.

Embodiments may achieve advantages. By using the tri-layered structure instead of a single layer structure for the electrodes of the MIM capacitors, the surface roughness of the electrodes is reduced. The reduced surface roughness alleviates or avoids performance degradation in terms of VBD and TDDB. As a result, the performance and reliability of the semiconductor device formed are improved.

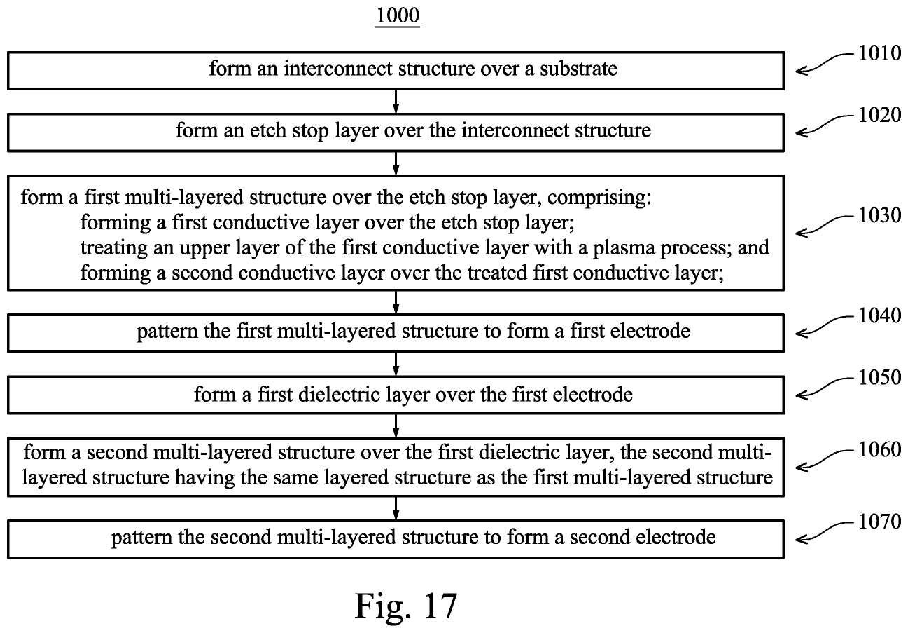

FIG. 17 illustrates a flow chart of a method of fabricating a semiconductor device, in accordance with some embodiments. It should be understood that the embodiment method shown in FIG. 17 is merely an example of many possible embodiment methods. One of ordinary skill in the art would recognize many variations, alternatives, and modifications. For example, various steps as illustrated in FIG. 17 may be added, removed, replaced, rearranged, or repeated.

Referring to FIG. 17, at block 1010, an interconnect structure is formed over a substrate. At block 1020, an etch stop layer is formed over the interconnect structure. At block 1030, a first multi-layered structure is formed over the etch stop layer, comprising: forming a first conductive layer over the etch stop layer; treating an upper layer of the first conductive layer with a plasma process; and forming a second conductive layer over the treated first conductive layer. At block 1040, the first multi-layered structure is patterned to form a first electrode. At block 1050, a first dielectric layer is formed over the first electrode. At block 1060, a second multi-layered structure is formed over the first dielectric layer, the second multi-layered structure having the same layered structure as the first multi-layered structure. At block 1070, the second multi-layered structure is formed to form a second electrode.

In an embodiment, a method of forming a semiconductor device includes: forming an interconnect structure over a substrate; forming an etch stop layer over the interconnect structure; and forming a first multi-layered structure over the etch stop layer, comprising: forming a first conductive layer over the etch stop layer; treating an upper layer of the first conductive layer with a plasma process; and forming a second conductive layer over the treated first conductive layer. The method further includes: patterning the first multi-layered structure to form a first electrode; forming a first dielectric layer over the first electrode; forming a second multi-layered structure over the first dielectric layer, the second multi-layered structure having the same layered structure as the first multi-layered structure; and patterning the second multi-layered structure to form a second electrode. In an embodiment, the first conductive layer is a polycrystalline material, wherein treating the upper layer of the first conductive layer converts the upper layer of the first conductive layer into an amorphous material. In an embodiment, the plasma process is performed using a gas source comprising nitrogen gas or a noble gas. In an embodiment, the first conductive layer and the second conductive layer are formed of the same polycrystalline material. In an embodiment, the first dielectric layer is formed of a high-k dielectric material. In an embodiment, the first electrode covers a first portion of the etch stop layer and exposes a second portion of the etch stop layer, wherein the first dielectric layer is formed conformally over the first electrode and over the second portion of the etch stop layer. In an embodiment, the second electrode is formed to have a stair shaped cross-section, wherein a first portion of the second electrode is laterally adjacent to the first electrode, and a second portion of the second electrode extends along an upper surface of the first electrode distal from the substrate. In an embodiment, the second portion of the second electrode exposes a first portion of the first dielectric layer at the upper surface of the first electrode. In an embodiment, the method further includes: forming a second dielectric layer over the second electrode and over the exposed first portion of the first dielectric layer; and forming a third electrode over the second dielectric layer, wherein the third electrode is formed to have a stair-shaped cross-section, wherein a first portion of the third electrode is laterally adjacent to the second portion of the second electrode, and a second portion of the third electrode extends along an upper surface of the second portion of the second electrode distal from the substrate. In an embodiment, forming the third electrode comprises: forming a third multi-layered structure over the second dielectric layer, the third multi-layered structure having the same layered structure as the first multi-layered structure; and patterning the third multi-layered structure to form the third electrode. In an embodiment, forming the third electrode comprises: forming a single conductive layer over the second dielectric layer; and patterning the single conductive layer to form the third electrode. In an embodiment, the method further includes: forming a first via that extends through the first portion of the second electrode; and forming a second via that extends through the first portion of the third electrode and the first electrode.

In an embodiment, a method of forming a semiconductor device includes: forming a transistor over a substrate; forming an etch stop layer over the transistor and the substrate; and forming metal-insulator-metal (MIM) capacitors over the etch stop layer, comprising: forming a bottom electrode over the etch stop layer, wherein the bottom electrode has a layered structure and comprises a first conductive layer, a second conductive layer, and a third conductive layer in-between, wherein the first conductive layer and the second conductive layer are formed of a polycrystalline material, and the third conductive layer is formed of an amorphous material, wherein the bottom electrode is formed to cover a first portion of the etch stop layer and expose a second portion of the etch stop layer; forming a first dielectric layer over the second portion of the etch stop layer and over the bottom electrode; forming a middle electrode over the first dielectric layer; forming a second dielectric layer over the middle electrode; and forming a top electrode over the second dielectric layer. In an embodiment, forming the bottom electrode comprises: forming a first layer of the polycrystalline material over the etch stop layer; converting an upper layer of the first layer of the polycrystalline material into the amorphous material using a plasma process; and after the plasma process, forming a second layer of the polycrystalline material over the amorphous material. In an embodiment, the middle electrode is formed to have the same layered structure as the bottom electrode. In an embodiment, the middle electrode has a first stair shaped cross-section, and the top electrode has a second stair shaped cross-section, wherein the first dielectric layer is partially covered by the middle electrode, and the second dielectric layer is partially covered by the top electrode. In an embodiment, the method further includes: forming a first via that extends through the first dielectric layer, the second dielectric layer, and the middle electrode; and forming a second via that extends through the first dielectric layer, the second dielectric layer, the bottom electrode, and the top electrode.

In an embodiment, a semiconductor device includes: a substrate having a transistor; an etch stop layer over the substrate; and metal-insulator-metal (MIM) capacitors over the etch stop layer, comprising: a bottom electrode over the etch stop layer, wherein the etch stop layer is partially covered by the bottom electrode, wherein the bottom electrode has a layered structure and comprises: a first layer of a polycrystalline material; a second layer of the polycrystalline material; and a third layer of an amorphous material between the first layer and the second layer; a first dielectric layer over the bottom electrode and the etch stop layer; a middle electrode over the first dielectric layer, wherein the middle electrode has the same layered structure as the bottom electrode; a second dielectric layer over the middle electrode; and a top electrode over the second dielectric layer. In an embodiment, the first dielectric layer is partially covered by the middle electrode, wherein the second dielectric layer is partially covered by the top electrode. In an embodiment, the middle electrode is interposed between a first portion of the first dielectric layer and a first portion of the second dielectric layer, wherein a second portion of the first dielectric layer contacts and extends along a second portion of the second dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, the method comprising:
forming an interconnect structure over a substrate;
forming an etch stop layer over the interconnect structure;
forming a first multi-layered structure over the etch stop layer, comprising:
forming a first conductive layer over the etch stop layer;
treating an upper layer of the first conductive layer with a plasma process; and
forming a second conductive layer over the treated first conductive layer;
patterning the first multi-layered structure to form a first electrode;
forming a first dielectric layer over the first electrode;
forming a second multi-layered structure over the first dielectric layer, the second multi-layered structure having the same layered structure as the first multi-layered structure; and
patterning the second multi-layered structure to form a second electrode.

2. The method of claim 1, wherein the first conductive layer is a polycrystalline material, wherein treating the upper layer of the first conductive layer converts the upper layer of the first conductive layer into an amorphous material.

3. The method of claim 2, wherein the plasma process is performed using a gas source comprising nitrogen gas or a noble gas.

4. The method of claim 2, wherein the first conductive layer and the second conductive layer are formed of the same polycrystalline material.

5. The method of claim 1, wherein the first dielectric layer is formed of a high-k dielectric material.

6. The method of claim 1, wherein the first electrode covers a first portion of the etch stop layer and exposes a second portion of the etch stop layer, wherein the first dielectric layer is formed conformally over the first electrode and over the second portion of the etch stop layer.

7. The method of claim 1, wherein the second electrode is formed to have a stair shaped cross-section, wherein a first portion of the second electrode is laterally adjacent to the first electrode, and a second portion of the second electrode extends along an upper surface of the first electrode distal from the substrate.

8. The method of claim 7, wherein the second portion of the second electrode exposes a first portion of the first dielectric layer at the upper surface of the first electrode.

9. The method of claim 8, further comprising:
forming a second dielectric layer over the second electrode and over the exposed first portion of the first dielectric layer; and
forming a third electrode over the second dielectric layer, wherein the third electrode is formed to have a stair-shaped cross-section, wherein a first portion of the third electrode is laterally adjacent to the second portion of the second electrode, and a second portion of the third electrode extends along an upper surface of the second portion of the second electrode distal from the substrate.

10. The method of claim 9, wherein forming the third electrode comprises:
forming a third multi-layered structure over the second dielectric layer, the third multi-layered structure having the same layered structure as the first multi-layered structure; and
patterning the third multi-layered structure to form the third electrode.

11. The method of claim 9, wherein forming the third electrode comprises:
forming a single conductive layer over the second dielectric layer; and
patterning the single conductive layer to form the third electrode.

12. The method of claim 9, further comprising:
forming a first via that extends through the first portion of the second electrode; and
forming a second via that extends through the first portion of the third electrode and the first electrode.

13. A method of forming a semiconductor device, the method comprising:
forming a transistor over a substrate;
forming an etch stop layer over the transistor and the substrate; and
forming metal-insulator-metal (MIM) capacitors over the etch stop layer, comprising:
forming a bottom electrode over the etch stop layer, wherein the bottom electrode has a layered structure and comprises a first conductive layer, a second conductive layer, and a third conductive layer in-between, wherein the first conductive layer and the second conductive layer are formed of a polycrystalline material, and the third conductive layer is formed of an amorphous material, wherein the bottom electrode is formed to cover a first portion of the etch stop layer and expose a second portion of the etch stop layer;
forming a first dielectric layer over the second portion of the etch stop layer and over the bottom electrode;
forming a middle electrode over the first dielectric layer;
forming a second dielectric layer over the middle electrode; and
forming a top electrode over the second dielectric layer.

14. The method of claim 13, wherein forming the bottom electrode comprises:
forming a first layer of the polycrystalline material over the etch stop layer;
converting an upper layer of the first layer of the polycrystalline material into the amorphous material using a plasma process; and
after the plasma process, forming a second layer of the polycrystalline material over the amorphous material.

15. The method of claim 14, wherein the middle electrode is formed to have the same layered structure as the bottom electrode.

16. The method of claim 15, wherein the middle electrode has a first stair shaped cross-section, and the top electrode has a second stair shaped cross-section, wherein the first dielectric layer is partially covered by the middle electrode, and the second dielectric layer is partially covered by the top electrode.

17. The method of claim 16, further comprising:
forming a first via that extends through the first dielectric layer, the second dielectric layer, and the middle electrode; and
forming a second via that extends through the first dielectric layer, the second dielectric layer, the bottom electrode, and the top electrode.

18. A semiconductor device comprising:
a substrate having a transistor;
an etch stop layer over the substrate; and
metal-insulator-metal (MIM) capacitors over the etch stop layer, comprising:
a bottom electrode over the etch stop layer, wherein the etch stop layer is partially covered by the bottom electrode, wherein the bottom electrode has a layered structure and comprises:
a first layer of a polycrystalline material;
a second layer of the polycrystalline material; and
a third layer of an amorphous material between the first layer and the second layer;
a first dielectric layer over the bottom electrode and the etch stop layer;
a middle electrode over the first dielectric layer, wherein the middle electrode has the same layered structure as the bottom electrode;
a second dielectric layer over the middle electrode; and
a top electrode over the second dielectric layer.

19. The semiconductor device of claim 18, wherein the first dielectric layer is partially covered by the middle electrode, wherein the second dielectric layer is partially covered by the top electrode.

20. The semiconductor device of claim 18, wherein the middle electrode is interposed between a first portion of the first dielectric layer and a first portion of the second dielectric layer, wherein a second portion of the first dielectric layer contacts and extends along a second portion of the second dielectric layer.
